(19) United States
(12) Patent Application Publication
(10) Pub. No.: US 2004/0209389 A1
(43) Pub. Date: Oct. 21, 2004

(54) Manufacturing method for liquid crystal display panels having high aperture ratio

(76) Inventor: Gou Tsau Liang, Jia-Yi Hsien (TW)

Correspondence Address: VOLENTINE FRANCOS, PLLC, ONE FREEDOM SQUARE, 11951 FREEDOM DRIVE SUITE 1260, RESTON, VA, 20190, US

(21) Appl. No.: 10/752,502

(22) Filed: Jan. 8, 2004

(30) Foreign Application Priority Data
Apr. 17, 2003 (TW) 092109176

(51) Int. Cl. H01L 21/00

(52) U.S. Cl. 438/30

(57) ABSTRACT

A protection layer is formed on a transparent substrate having a plurality of thin film transistors, and an exposure step is then carried out by means of a half-tone mask. An outer lead bonding area is located on the periphery of the transparent substrate. After the exposure and development steps, most of the protection layer in the outer lead bonding area is removed. With an etching step, the top of an insulation layer of the outer lead bonding area is exposed and a plurality of via holes are formed in the insulation layer, thus a metal layer is exposed from the via holes as outer lead bonding pads. Finally, a transparent conductive layer with desired patterns is formed on the protection layer, and the transparent conductive layer is extended into the via holes of the protection layer to connect with the thin film transistors.

### BACKGROUND OF THE INVENTION

1. Field of the Invention

The present invention relates to a manufacturing method for liquid crystal display panels having a high aperture ratio, and more particularly to a manufacturing method for liquid crystal display panels having a high aperture ratio to reduce the number of masks and increase reliability.

2. Description of the Related Art

A liquid crystal display panel comprises a transparent substrate, which has a plurality of thin film transistors, and a color filter substrate. The two substrates are stacked in a parallel manner, and are sealed with a sealing compound applied to their periphery. The space enclosed by them is filled with liquid crystal molecules. As shown in FIG. 1, the surface of the transparent substrate 11 comprises a thin film transistor circuit area (or an “active area”) 1 and an outer lead bonding area 2.

A gate electrode 121 and a gate line 122 are patterned and formed on the transparent substrate 11 during the first photo-etching process (PEP). Then, an insulation layer 13, an amorphous silicon layer 14 and an etching stopper layer 15 are deposited on the transparent substrate 11 before the second photo-etching process is completed. In this regard, both the insulation layer 13 and the etching stopper layer 15 can be made from silicon nitride (SiNₓ) or silicon oxygen (SiOₓ). What is carried out next is the third photo-etching process wherein a N+ amorphous silicon layer 16 and a source/drain metal layer 17 are deposited on the transparent substrate 11, and then subjected to exposure, development and etching, so as to define the circuit pattern of the source/drain metal layer 17. Up to this point, a related structure of the thin film transistor 3 is formed. However, an additional silicon nitride layer 131 may be deposited thereon to protect the thin film transistor 3 and other corresponding circuits.

Then, a protection layer 18 is deposited on the aforementioned structure of the thin film transistor 3 and the fourth photo-etching process starts. The protection layer 18 can be made from organic, transparent materials and SiNₓ, etc. It is necessary to planarize the surface of the protection layer 18 for the sake of a high aperture ratio. For this reason, when it comes to a manufacturing process intended for a high aperture ratio, the protection layer 18 is best made from organic transparent materials or a combination of SiNₓ and organic transparent materials. After exposure, development and etching, a plurality of via holes 124 and 125 are formed in the protection layer 18. The via hole 124 exposes the gate line 122 to circumstances as the outer lead bonding pad 123. Finally, a transparent electrically conductive layer 19 is patterned on the surface of the protection layer 18 and inside the via hole 125 to function as a pixel electrode.

FIG. 2 is a top view of the position of a conventional transparent substrate on which thin film transistors are formed and that of a sealant. The outer lead bonding pad 123 is disposed around the transparent substrate 11 to be electrically connected to the outer lead of driving devices. The sealant 40 seals liquid crystal molecules in between the transparent substrate 11 and a color filter substrate (not shown).

The sealant 40 is disposed above the protection layer 18. In general, the sealant 40 is made from epoxy resins, which are harder than the protection layer 18, as shown in FIG. 3. If the protection layer 18 is made from acrylate or an organic material, which is relatively soft, it will be more likely to crack when a force is applied to it, allowing the liquid crystal molecules to seep out of the space enclosed by the transparent substrate 11 and the color filter substrate through a crack. On the other hand, the succeeding bonding process for bonding an outer lead has to be preceded by coating the outer lead bonding area 2 with an anisotropic conductive film (ACF) 31, as shown in FIG. 4. However, the via hole 124 is so deep that contact impedance arises between the electrically conductive particles 311 in the anisotropic conductive film 31 and the outer lead bonding pad 123.

To solve the aforesaid problem, another conventional technology involves forming gate lines 122′ on the surface of a transparent substrate 11′ first, as shown in FIG. 5(a). Then, a contact window is etched into the insulation layer 13′ and the silicon nitride layer 131′, exposing the gate line 122′ to enable it to function as the outer lead bonding pad 123′. In addition, the silicon nitride layer 131′ may be omitted, if indicated by the actual manufacturing process. Afterwards, the protection layer 18′ is defined in the area outside a outer lead bonding area 2′ to allow the sealant 40 to adhere to the insulation layer 13′ or the silicon nitride layer 131′, both of which are harder than the protection layer 18′, as shown in FIG. 5(b). Although the aforesaid method is useful in solving the cracking problem, it requires one more photo-etching process. Furthermore, on the formation of the protection layer 18′, the exposed outer lead bonding pad 123′ brings contamination. Hence, the contaminants have to be removed by means of an additional plasma-etching step.

No conventional methods solved the problems regarding the cracking problem, contamination and the complicated manufacturing processes, and thus they failed to meet market needs.

### SUMMARY OF THE INVENTION

An objective of the present invention is to provide a manufacturing method for liquid crystal display panels having a high aperture ratio. It involves forming a protection layer on a transparent substrate, using a half-tone photo-etching process, so as to enable a sealant to adhere to an insulation layer directly underneath it and reduce the number of masks used in the manufacturing process by one.

The second objective of the present invention is to provide a manufacturing method for liquid crystal display panels having a high aperture ratio wherein the outer lead bonding pads are exposed only after the formation of a protection layer, sparing the process of removing contaminants from the outer lead bonding pads.

The third objective of the present invention is to provide a manufacturing method for liquid crystal display panels having a high aperture ratio, with a view to increasing the reliability of the bonding between the driving devices and the outer lead bonding pads.

In order to achieve the objectives, the present invention discloses a manufacturing method for liquid crystal display panels having a high aperture ratio. A protection layer is formed on a transparent substrate having a plurality of thin film transistors, and an exposure step is then carried out by means of a half-tone mask. An outer lead bonding area is located on the periphery of the transparent substrate. After the exposure and development steps, most of the protection layer in the outer lead bonding area is removed. With an etching step, the top of an insulation layer of the outer lead bonding area is exposed and a plurality of via holes are formed in the insulation layer, and thus a metal layer is exposed from the via holes as outer lead bonding pads. Finally, a transparent conductive layer with the desired pattern is formed on the protection layer, and the transparent conductive layer is extended into the via holes of the protection layer to connect to the thin film transistors.

### BRIEF DESCRIPTION OF THE DRAWINGS

The invention will be described according to the appended drawings in which:

FIG. 1 shows the cross-sectional structure of a transparent substrate with thin film transistors in accordance with a conventional liquid crystal display;

FIG. 2 is a top view of the position of a conventional transparent substrate on which thin film transistors are formed and that of a sealant;

FIG. 3 shows the cross-sectional structure of the transparent substrate in FIG. 2;

FIG. 4 shows the transparent substrate of FIG. 3 pasted with an AFC;

FIGS. 5(a)-5(b) show the manufacturing steps of a transparent substrate with thin film transistors in accordance with a conventional liquid crystal display;

FIGS. 6(a)-6(d) show the manufacturing steps of a transparent substrate with thin film transistors in accordance with the first embodiment of the present invention;

FIG. 7 is a top view of the position of a transparent substrate on which thin film transistors are formed and that of a sealant in accordance with the present invention; and

FIG. 8 shows the cross-sectional structure of the transparent substrate in accordance with the second embodiment of the present invention.

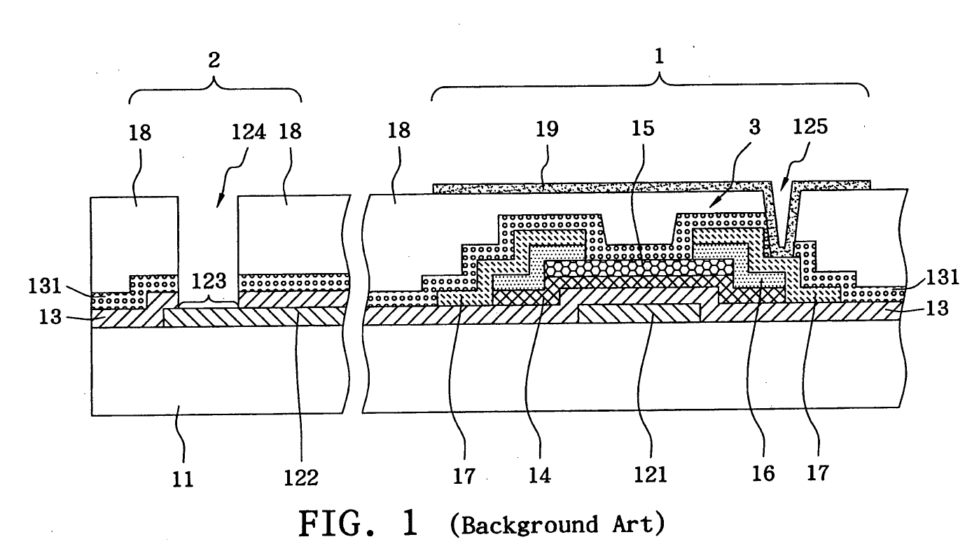

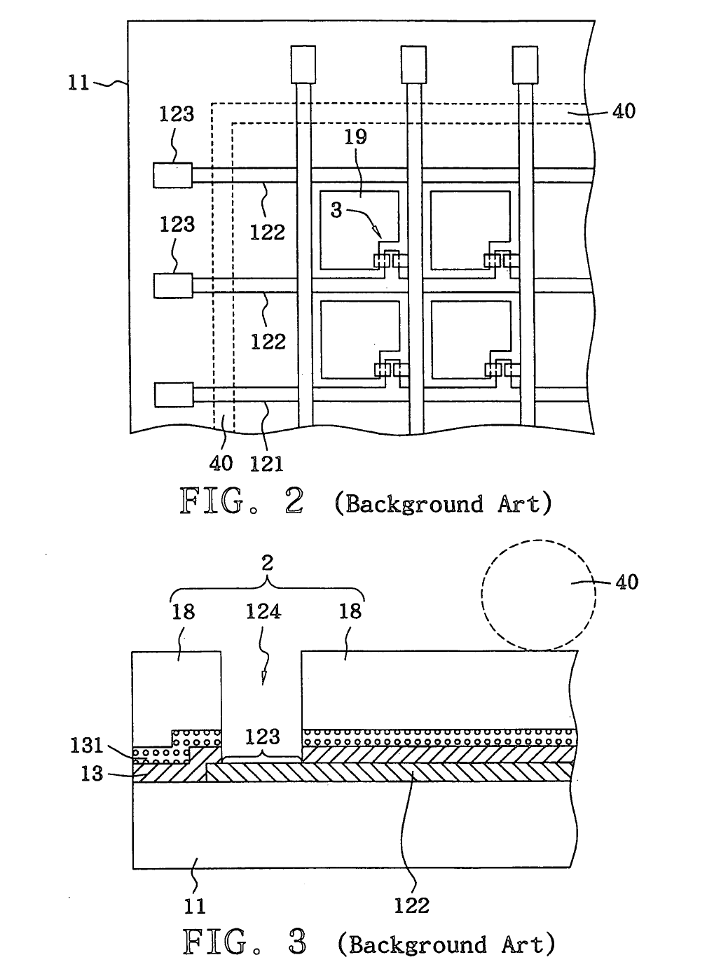

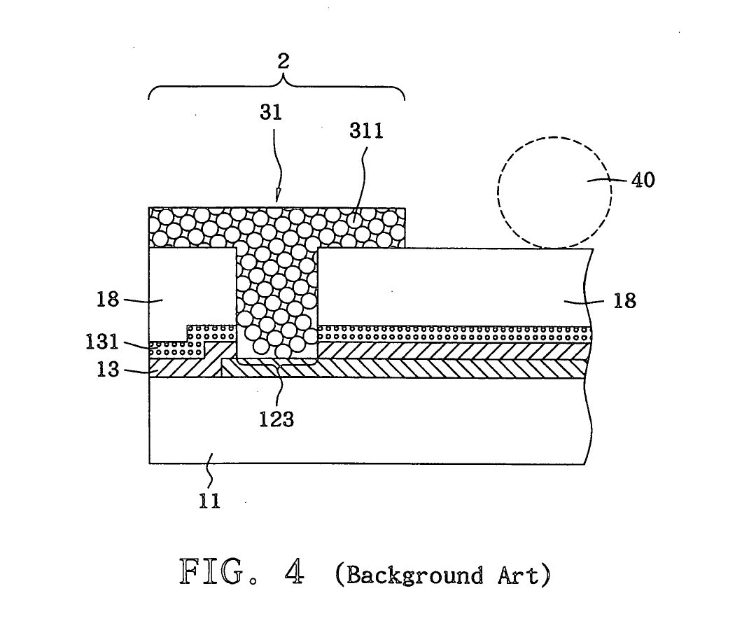

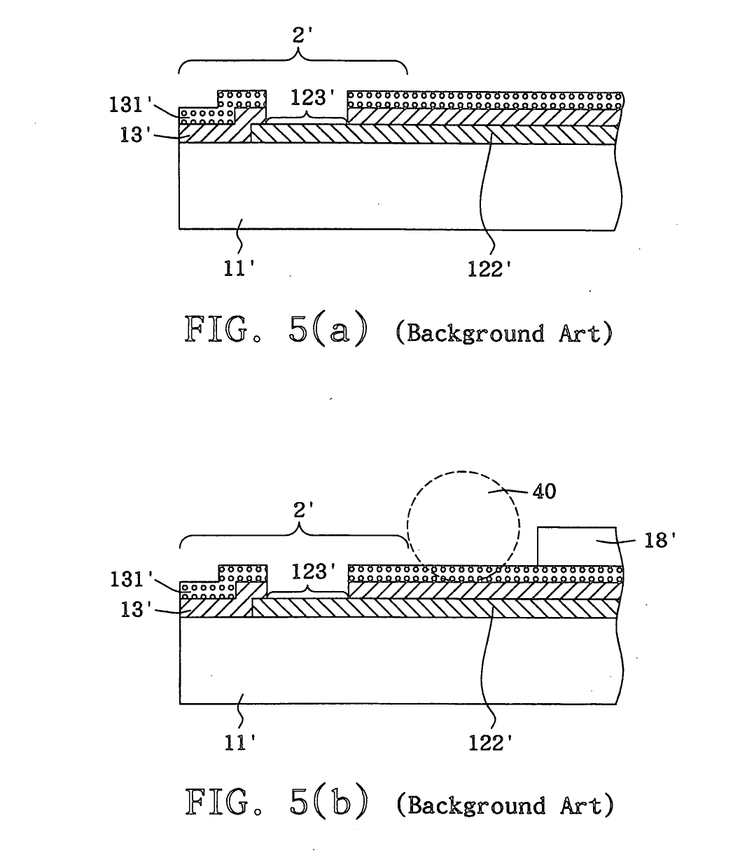

### PREFERRED EMBODIMENT OF THE PRESENT INVENTION

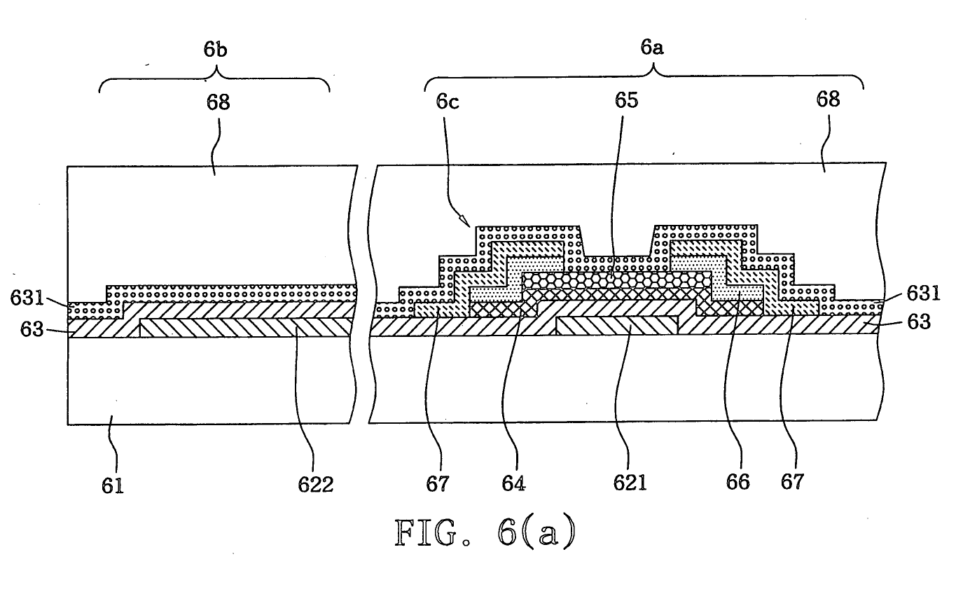

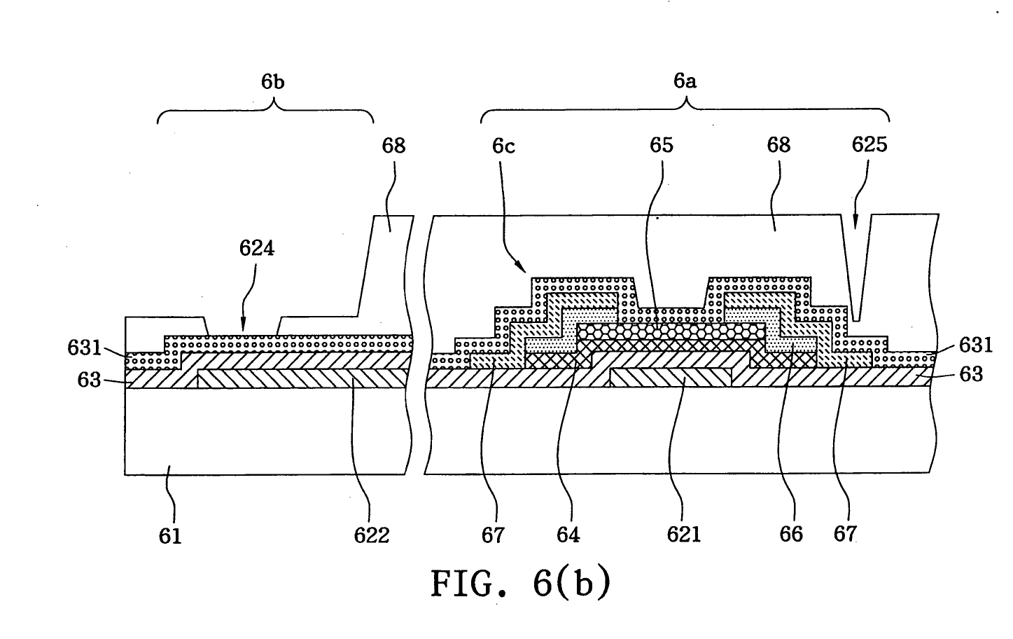

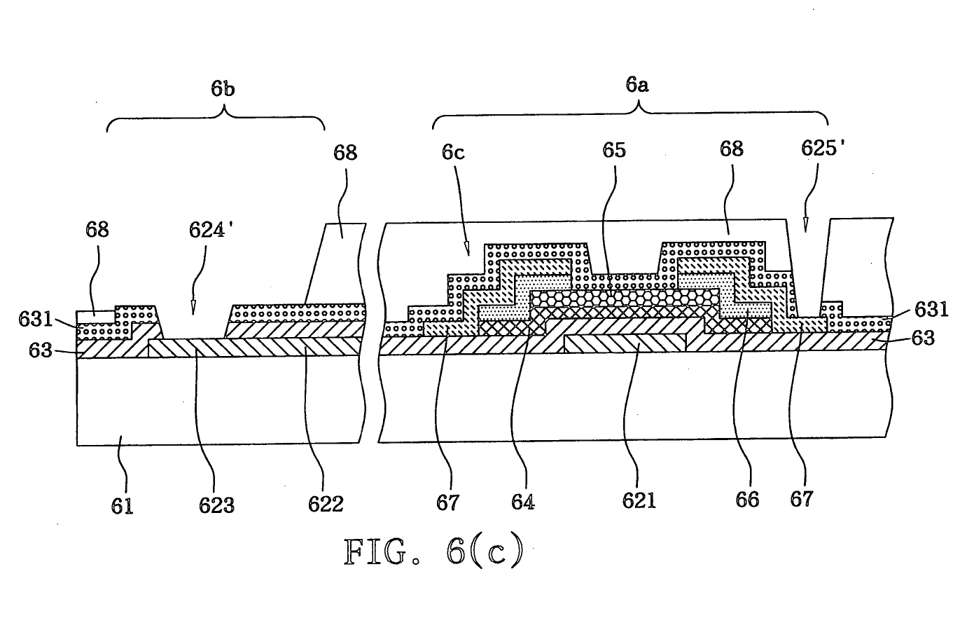

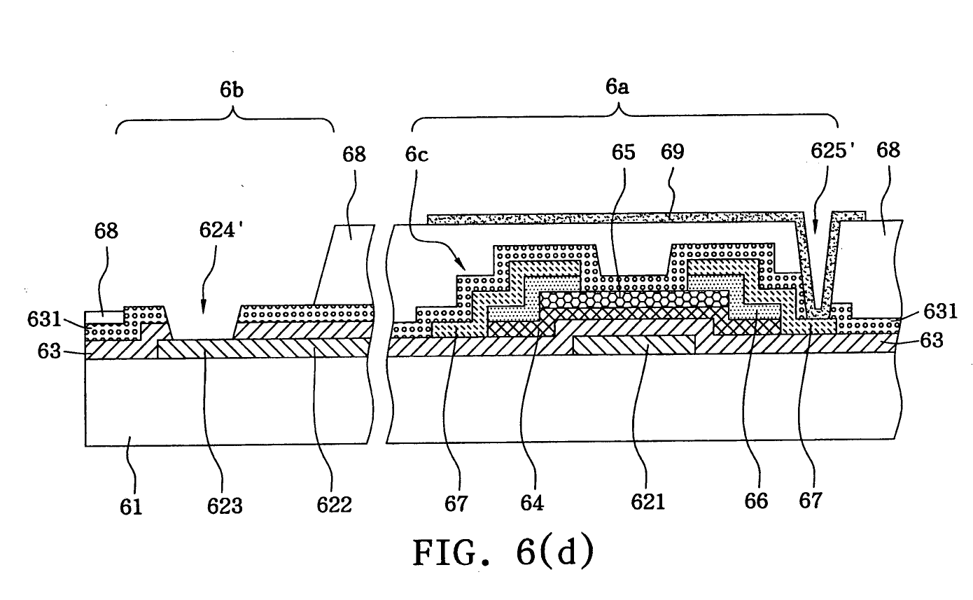

FIGS. 6(a)-6(d) show the manufacturing steps of a transparent substrate with thin film transistors in accordance with the first embodiment of the present invention. First , as shown in FIG. 6(a), gate electrodes 621 and gate lines 622 are patterned and formed on a transparent substrate 61 during the first photo-etching process. In this regard, the gate electrode 621 and gate line 622 can be made from materials like chromium, molybdenum, tantalum, tantalum molybdenate, tungsten molybdenate, aluminum, aluminum silicate and copper, etc. Then, an insulation layer 63, an amorphous silicon layer 64 and an etching stopper layer 65 are patterned and formed on the transparent substrate 61 before the second photo-etching process is completed. Both the insulation layer 63 and the etching stopper layer 65 are composed of insulating materials like silicon nitride, silica (SiOₓ) or silicon-oxide-nitride (SiOxNy). What is carried out next is the third photo-etching process wherein the desired patterns of both a N+ amorphous silicon layer 66 and a source/drain metal layer 67 are defined and formed on the transparent substrate 61. Up to this point, a related structure of a thin film transistor 6c has formed, and the thin film transistor 6c is called an etching stop structure.

Prior to the fourth photo-etching process, a layer of silicon nitride 631 and a protection layer 68 are formed on the transparent substrate 61, or, in other words, both the thin film transistor circuit area (or named an active area) 6a and the outer lead bonding area 6b are coated with a layer of silicon nitride 631 and a protection layer 68. The silicon nitride layer 631 may be omitted, if indicated by the actual manufacturing process. The protection layer 68 can be made from organic, insulating, transparent materials like acrylate or other kinds of plastics.

As shown in FIG. 6(b), the exposure step is carried out by means of a half-tone mask. Given the half-tone mask, on exposure, the surfaces of the protection layer 68 are of different desired thickness, so that openings 625 and 624 are formed in the thin film transistor circuit area 6a and the outer lead bonding area 6b, respectively. In general, the procedure of manipulating a half-tone mask is as follows: use transparent quartz as a substrate; coat the quartz with a chromium layer; a plurality of tiny openings intended to simulate a gray scale effect are disposed in the chromium layer; changes can be made in exposure depth and, on exposure, photoresist layers with various contours emerge, depending on the layout of the tiny binary openings. The present invention involves using a photoresist layer as the protection layer 68 so as to form the photoresist layer with various desired thickness in one single exposure/development step.

FIG. 6(c) shows the result of the etching steps illustrated with FIG. 6(b). The protection layer 68 varies in its desired thickness, whereas an opening 624′ is formed in the original opening 624 to expose the outer lead bonding pad 623. Given the etching process, the opening 625 previously formed in the thin film transistor circuit area 6a expands to become a via hole 625′ which then exposes the source/drain metal layer 67.

As shown in FIG. 6(d), a transparent conductive layer (for example, an ITO layer) 69 is formed and defined on the surface of the protection layer 68 and inside the via hole 625′.

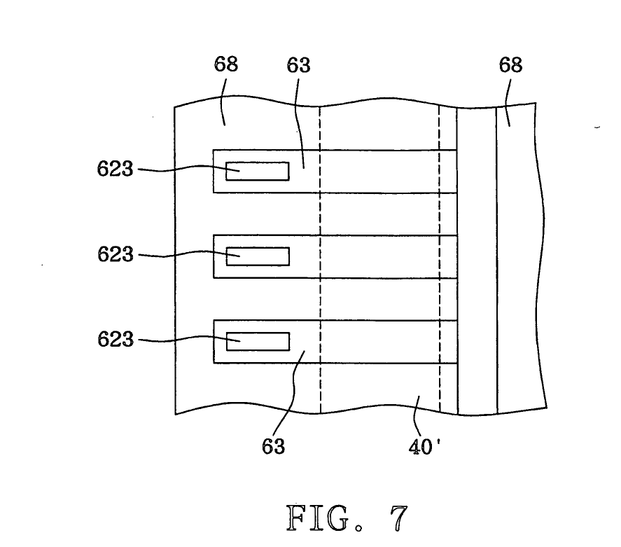

FIG. 7 is a top view of the conventional position of the outer lead bonding area 6b and that of a sealant 40′ in accordance with the present invention. The sealant 40′ directly adheres to the top of the insulation layer 63, thus it has sufficient supporting strength to fix the sealant 40′. All the constituents are covered with the protection layer 68, with the exception of the exposed insulation layer 63.

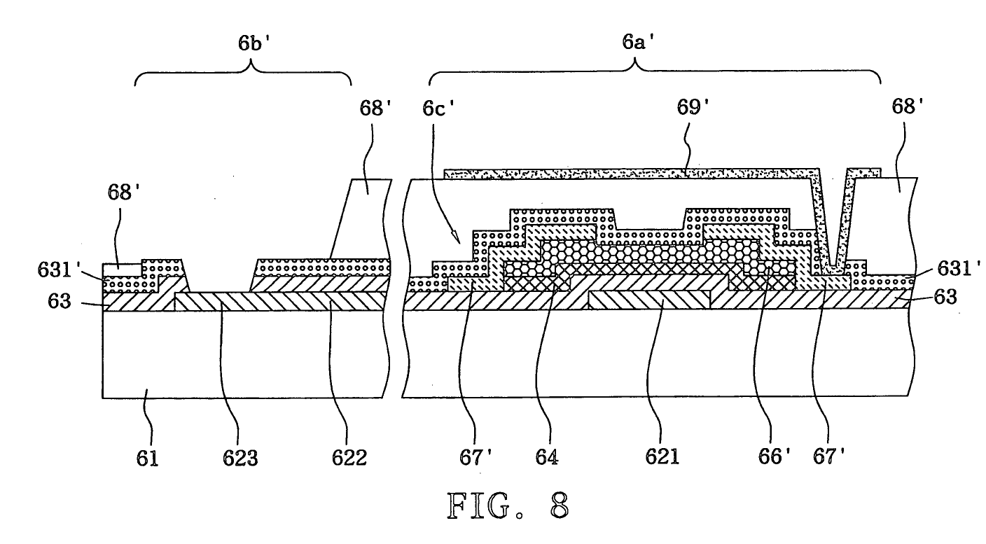

FIG. 8 shows the cross-sectional structure of the transparent substrate in accordance with the BCE (back-channel etch) structure embodiment of the present invention. The difference between the structure of the back-channel etch and the aforesaid etching stop structure is that, the former does not have an etching stopper layer, but it has a N+ amorphous silicon layer 66′ and a source/drain metal layer 67′ formed on the amorphous silicon layer 64. The remaining steps are identical to those in the first embodiment, that is, the protection layer 68′ is defined in the thin film transistor circuit area 6a′ and the outer lead bonding area 6b′ using a half-tone mask. Lastly, the transparent conductive layer 69′ is defined and formed on the protection layer 68′. An additional silicon nitride layer 631 ′ may be deposited prior to the formation of the protection layer 68′.

The above-described embodiments of the present invention are intended to be illustrative only. Numerous alternative embodiments may be devised by persons skilled in the art without departing from the scope of the following claims.

What is claimed is:

1. A manufacturing method for liquid crystal display panels having a high aperture ratio, comprising the steps of:
providing a transparent substrate with thin film transistors forming therein, and the periphery of the transparent substrate having an outer lead bonding area formed by covering an insulation layer over metal wires;
forming a protection layer over the thin film transistors of the transparent substrate and outer lead bonding area;
applying a photo-etching process by a half-tone mask to the protection layer so as to remove a part of the protection layer at the outer lead bonding area for exposing the insulation layer on which outer lead bonding pads are predefinedly located; and
etching the remaining protection layer and the exposed insulation layer for exposing upper portions of the insulation layer and generating via holes through the insulation layer so as to expose the metal wires.

2. The manufacturing method for liquid crystal display panels having a high aperture ratio of claim 1, wherein the protection layer above the thin film transistors has at least one via hole formed by the etching process.

3. The manufacturing method for liquid crystal display panels having a high aperture ratio of claim 2, further comprising the step of:
forming a transparent conductive layer on the protection layer and inside the via holes so as to electrically contact the thin film transistors.

4. The manufacturing method for liquid crystal display panels having a high aperture ratio of claim 1, wherein the thin film transistor is a transistor having an etching structure.

5. The manufacturing method for liquid crystal display panels having a high aperture ratio of claim 1, wherein the thin film transistor is a transistor having a back-channel etching structure.

6. The manufacturing method for liquid crystal display panels having a high aperture ratio of claim 1, wherein the exposed portions of the metal wires are the outer lead bonding pads.

7. The manufacturing method for liquid crystal display panels having a high aperture ratio of claim 1, wherein the protection layer is made from a transparent organic material.

8. The manufacturing method for liquid crystal display panels having a high aperture ratio of claim 7, wherein the organic material is acrylate.

9. The manufacturing method for liquid crystal display panels having a high aperture ratio of claim 1, further comprising the step of:
sealing the liquid crystal display panel by pasting a sealant on the exposed portions of the insulation layer.

10. The manufacturing method for liquid crystal display panels having a high aperture ratio of claim 1, further comprising the step of:
interposing a silicon nitride layer between the insulation layer and the protection layer.

11. The manufacturing method for liquid crystal display panels having a high aperture ratio of claim 1, wherein the protection layer is a photoresist layer.
